(19) United States
(12) Patent Application Publication
(10) Pub. No.: US 2014/0154463 A1
(43) Pub. Date: Jun. 5, 2014

(54) SUBSTRATE STRUCTURE AND MANUFACTURING METHOD THEREOF

(71) Applicant: UNIMICRON TECHNOLOGY CORP., Taoyuan (TW)

(72) Inventor: Shun-Hsiang Liang, Hsinchu County (TW)

(73) Assignee: UNIMICRON TECHNOLOGY CORP., Taoyuan (TW)

(21) Appl. No.: 13/737,954

(22) Filed: Jan. 10, 2013

(30) Foreign Application Priority Data
Dec. 4, 2012 (TW) 101145509

(51) Int. Cl. B23K 26/38; H05K 1/11

(52) U.S. Cl. CPC B23K 26/381; H05K 1/115
USPC 428/131; 264/400

(57) ABSTRACT

A substrate structure includes an insulation base material and a through hole. The through hole passes through the insulation base material. Besides, the through hole has a first opening, a second opening, and a third opening communicated with one another. The third opening is located between the first opening and the second opening. A first included angle is formed between an inner wall of the first opening and an inner wall of the third opening. A second included angle is formed between an inner wall of the second opening and the inner wall of the third opening. The minimum diameter of the third opening is at the center of the through hole and defines a neck end portion. Diameters of the first opening and the second opening gradually decrease in a direction toward the neck end portion.

### CROSS-REFERENCE TO RELATED APPLICATION

This application claims the priority benefit of Taiwan application serial no. 101145509, filed on Dec. 4, 2012. The entirety of the above-mentioned patent application is hereby incorporated by reference herein and made a part of this specification.

### BACKGROUND OF THE INVENTION

1. Field of the Invention

The invention relates to a substrate structure and a manufacturing method thereof. More particularly, the invention relates to a substrate structure having a through hole and a manufacturing method of the substrate structure.

2. Description of Related Art

In the existing circuit board technical field, circuits on a circuit board are often made of copper foil. Due to the large coefficient of thermal conductivity of the copper foil, the copper foil is able to effectively conduct heat. When the copper foil is directly irradiated by a laser beam, the heat generated by the laser beam may be rapidly dissipated by the copper foil, such that the heat is not apt to be accumulated in an insulation layer below the copper foil. Thereby, it is rather difficult to enhance aperture precision. A direct laser drilling (DLD) process performed on a surface of the copper foil with use of a laser beam is efficient and cost-effective in comparison with a conventional mechanical drilling process; nevertheless, the DLD process may result in an over-etch defect, a void defect, and the like. Specifically, a through hole of the insulation layer is supposed to be filled with a conductive material. However, since a diameter of one end of the through hole is smaller than a diameter of the other end of the through hole, the end of the through hole having the small diameter is first filled with and sealed by the deposited conductive material. As a result, the conductive material that is not able to be fully deposited in the through hole renders the void defect.

### SUMMARY OF THE INVENTION

The invention is directed to a substrate structure capable of preventing a void defect from occurring in a subsequent via filling plating process.

The invention is also directed to a manufacturing method for manufacturing the aforesaid substrate structure.

In an embodiment of the invention, a substrate structure that includes an insulation base material and a through hole is provided. The through hole passes through the insulation base material. Besides, the through hole has a first opening, a second opening, and a third opening communicated with one another. The third opening is located between the first opening and the second opening. A first included angle is formed between an inner wall of the first opening and an inner wall of the third opening, and a second included angle is formed between an inner wall of the second opening and the inner wall of the third opening. The minimum diameter of the third opening is at the center of the through hole and defines a neck end portion. Diameters of the first opening and the second opening gradually decrease in a direction toward the neck end portion.

According to an embodiment of the invention, a thickness of the insulation base material ranges from about 100 μm to about 400 μm.

According to an embodiment of the invention, the inner wall of the third opening is a vertical surface, and the diameter of the third opening has a constant value.

According to an embodiment of the invention, the second included angle is substantially greater than the first included angle.

According to an embodiment of the invention, the inner wall of the third opening is an inclined surface, and the diameter of the third opening gradually decreases in a direction from the first opening to the neck end portion.

According to an embodiment of the invention, the second included angle is substantially greater than the first included angle.

In an embodiment of the invention, a manufacturing method of a substrate structure includes following steps. An insulation base material is provided. The insulation base material has an upper surface and a lower surface opposite to each other. First laser treatment is performed on the upper surface of the insulation base material to form a first opening. Second laser treatment is performed on the lower surface of the insulation base material to for a second opening, and the second opening communicates with the first opening, and the communicated first and second openings define an initial neck end portion. Third laser treatment is performed on the upper surface or the lower surface of the insulation base material according to a location of the initial neck end portion to form a third opening. The first opening, the second opening, and the third opening are communicated with one another and define a through hole. The third opening is located between the first opening and the second opening. A first included angle is formed between an inner wall of the first opening and an inner wall of the third opening, and a second included angle is formed between an inner wall of the second opening and the inner wall of the third opening. The minimum diameter of the third opening is at the center of the through hole and defines a neck end portion. Diameters of the first opening and the second opening gradually decrease in a direction toward the neck end portion.

According to an embodiment of the invention, a thickness of the insulation base material ranges from about 100 μm to about 400 μm.

According to an embodiment of the invention, laser energy of the first laser treatment, laser energy of the second laser treatment, and laser energy of the third laser treatment all range from about 5 mJ to about 15 mJ; laser pulse time of the first laser treatment, laser pulse time of the second laser treatment, and laser pulse time of the third laser treatment all range from about 5 microseconds to about 20 microseconds.

According to an embodiment of the invention, the inner wall of the third opening is a vertical surface, and the diameter of the third opening has a constant value.

According to an embodiment of the invention, the second included angle is substantially greater than the first included angle.

According to an embodiment of the invention, the inner wall of the third opening is an inclined surface, and the diameter of the third opening gradually decreases in a direction from the first opening to the neck end portion.

According to an embodiment of the invention, the second included angle is substantially greater than the first included angle.

In view of the above, the location of the neck end portion of the through hole is at the center of the through hole. Hence, when a via filling plating process is subsequently performed on the substrate structure, the conventional void issue (i.e., the end of the through hole with the small diameter is first filled with and sealed by the deposited conductive material) may be prevented. Consequently, the design of the substrate structure described herein is conducive to improvement of yield of subsequent manufacturing processes. In addition, the location of the neck end portion is adjusted through the third laser treatment, thus increasing reliability of the substrate structure in subsequent manufacturing processes.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1A through FIG. 1C are schematic cross-sectional views illustrating a manufacturing method of a substrate structure according to an embodiment of the invention.

FIG. 2 is a schematic cross-sectional view illustrating a substrate structure according to an embodiment of the invention.

### DETAILED DESCRIPTION OF DISCLOSED EMBODIMENTS

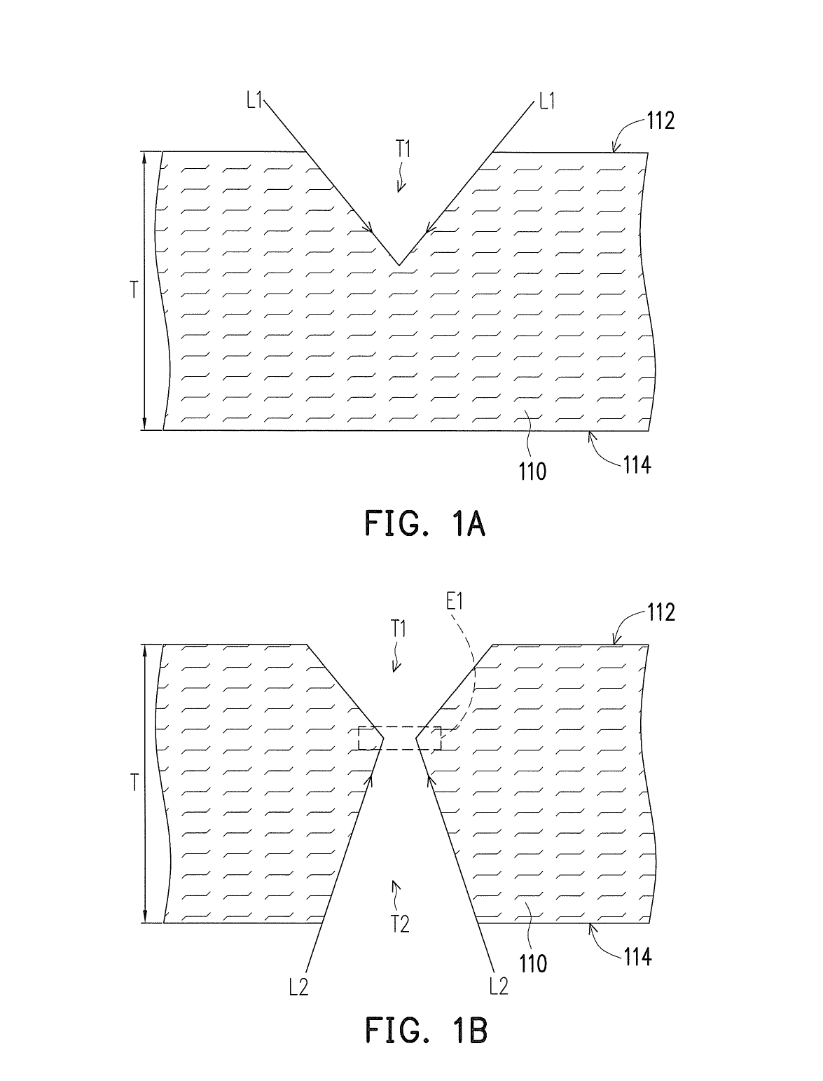

FIG. 1A through FIG. 1C are schematic cross-sectional views illustrating a manufacturing method of a substrate structure according to an embodiment of the invention. With reference to FIG. 1A, in the manufacturing method of the substrate structure described herein, an insulation base material 110 is provided. Here, the insulation base material 110 has an upper surface 112 and a lower surface 114 that are opposite to each other. A thickness T of the insulation base material 110 ranges from about 100 μm to about 400 μm, and a material of the insulation base material 110 includes but is not limited to a glass fiber film, silicone resin, epoxy resin, or any other appropriate material.

As shown in FIG. 1A, first laser treatment is performed on the upper surface 112 of the insulation base material 110, i.e., the upper surface 112 of the insulation base material 110 is irradiated by a first laser beam L1, so as to form a first opening T1. Here, laser energy of the first laser treatment ranges from about 5 mJ to about 15 mJ, and laser pulse time of the first laser treatment with use of the first laser beam L1 ranges from about 5 microseconds to about 20 microseconds. In FIG. 1A, the first laser beam L1 employed in the first laser treatment does not completely penetrate the insulation base material 110. Certainly, in other embodiments that are not shown in the drawings, the first laser beam L1 employed in the first laser treatment may completely penetrate the insulation base material 110, which should not be construed as a limitation to the invention.

With reference to FIG. 1B, second laser treatment is performed on the lower surface 114 of the insulation base material 110, i.e., the lower surface 114 of the insulation base material 110 is irradiated by a second laser beam L2, so as to form a second opening T2. The second opening T2 communicates with the first opening T1, and the communicated first and second openings T1 and T2 collectively define an initial neck end portion E1. Here, laser energy of the second laser treatment ranges from about 5 mJ to about 15 mJ, and laser pulse time of the second laser treatment with use of the second laser beam L2 ranges from about 5 microseconds to about 20 microseconds. In FIG. 1B, the second laser beam L2 employed in the second laser treatment does not completely penetrate the insulation base material 110. Certainly, in other embodiments that are not shown in the drawings, the second laser beam L2 employed in the second laser treatment may completely penetrate the insulation base material 110, which should not be construed as a limitation to the invention. Here, the location of the initial neck end portion E1 is closer to the first opening T1 than to the second opening T2.

With reference to FIG. 1 C, third laser treatment is performed on the upper surface 112 of the insulation base material 110 according to a location of the initial neck end portion E1 to form a third opening T3. The first opening T1, the second opening T2, and the third opening T3 are communicated with one another and define a through hole H, and the third opening T3 is located between the first opening T1 and the second opening T2. A first included angle θ1 is formed between an inner wall of the first opening T1 and an inner wall of the third opening T3, and a second included angle θ2 is formed between an inner wall of the second opening T2 and the inner wall of the third opening T3. Particularly, the minimum diameter D3 of the third opening T3 is at a center of the through hole H and defines a neck end portion E2, and a diameter D1 of the first opening T1 and a diameter D2 of the second opening T2 gradually decrease in a direction toward the neck end portion E2. Here, a third laser beam L3 employed in the third laser treatment is perpendicular to the upper surface 112 of the insulation base material 110, laser energy of the third laser treatment ranges from about 5 mJ to about 15 mJ, and laser pulse time of the third laser treatment with use of the third laser beam L3 ranges from about 5 microseconds to about 20 microseconds.

Specifically, as shown in FIG. 1C, the inner wall of the third opening T3 is a vertical surface, and the diameter D3 of the third opening T3 has a constant value. Here, the neck end portion E2 is a plane. Both the inner wall of the first opening T1 and the inner wall of the second opening T2 are inclined surfaces. Additionally, the diameter D1 of the first opening T1 gradually decreases in a direction from the upper surface 112 of the insulation base material 110 to the neck end portion E2, and the diameter D2 of the second opening T2 gradually decreases in a direction from the lower surface 114 of the insulation base material 110 to the neck end portion E2. The second included angle θ2 is substantially greater than the first included angle θ1. So far, the substrate structure 100a is substantially formed.

It should be mentioned that the location of the initial neck end portion E1 is closer to the first opening T1 than to the second opening T2; therefore, the third laser treatment is performed on the upper surface 112 of the insulation base material 110. Certainly, in other embodiments that are not shown in the drawings, given that the location of the initial neck end portion E1 is closer to the second opening T2 than to the first opening T1, the third laser treatment is performed on the lower surface 114 of the insulation base material 110, so as to adjust the location of the initial neck end portion E1. According to this embodiment, the location of the initial neck end portion E1 may be adjusted through the third laser treatment, so as to obtain the neck end portion E2. Thereby, reliability of the substrate structure 100a may be improved in subsequent manufacturing processes (not shown).

As to the substrate structure 100a, please refer to FIG. 1C which illustrates that the substrate structure 100a described in the present embodiment includes the insulation base material 110 and the through hole H. The through hole H passes through the insulation base material 110. Besides, the through hole H has the first opening T1, the second opening T2, and the third opening T3 that are communicated with one another. The third opening T3 is located between the first opening T1 and the second opening T2. The first included angle θ1 is formed between the inner wall of the first opening T1 and the inner wall of the third opening T3, and the second included angle θ2 is formed between the inner wall of the second opening T2 and the inner wall of the third opening T3. The minimum diameter D3 of the third opening T3 is at the center of the through hole H and defines the neck end portion E2, and the diameter D1 of the first opening T1 and the diameter D2 of the second opening T2 gradually decrease in the direction toward the neck end portion E2. Here, the thickness T of the insulation base material 110 ranges from about 100 μm to about 400 μm.

In particular, according to the present embodiment, the inner wall of the third opening T3 is a vertical surface, and the diameter D3 of the third opening T3 has a constant value. Both the inner wall of the first opening T1 and the inner wall of the second opening T2 are inclined surfaces. Additionally, the diameter D1 of the first opening T1 gradually decreases in the direction from the upper surface 112 of the insulation base material 110 to the neck end portion E2, and the diameter D2 of the second opening T2 gradually decreases in the direction from the lower surface 114 of the insulation base material 110 to the neck end portion E2. The second included angle θ2 is substantially greater than the first included angle θ1.

The neck end portion E2 of the through hole H is at the center of the through hole H in the present embodiment, which means that the depth of the first opening T1 is substantially equal to the depth of the second opening T2. Therefore, when a via filling plating process is subsequently performed on the substrate structure 100a, the through hole H is filled with a conductive material (not shown) in a direction from the neck end portion E2 to the first and second openings T1 and T2. As such, the conventional void issue (i.e., the end of the through hole with the small diameter is first filled with and sealed by the deposited conductive material) may be prevented. Consequently, the design of the substrate structure 100a described herein is conducive to improvement of yield of subsequent manufacturing processes.

Note that reference numbers and some descriptions provided in the previous embodiment are also applied in the present embodiment. The same reference numbers represent the same or similar components in this and the previous embodiments, and repetitive descriptions are omitted. The omitted descriptions may be referred to as those described in the previous embodiments.

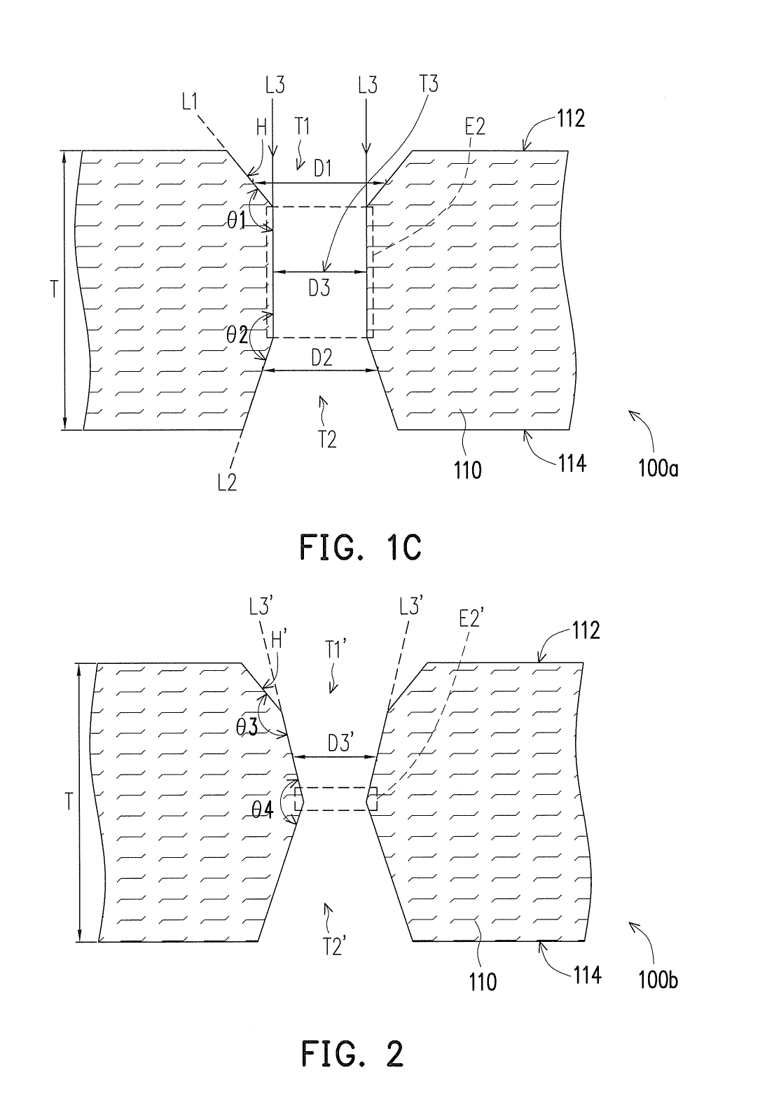

FIG. 2 is a schematic cross-sectional view illustrating a substrate structure according to an embodiment of the invention. With reference to FIG. 1C and FIG. 2, the substrate structure 100b described in the present embodiment is similar to the substrate structure 100a depicted in FIG. 1 C, while the main difference therebetween lies in that the inner wall of the third opening T3′ of the through hole H′ described herein is an inclined surface, and the diameter D3′ of the third opening T3′ gradually decreases in a direction from the first opening T1′ to the neck end portion E2′. The second included angle θ4 is substantially greater than the first included angle θ3.

As to manufacture, the substrate structure 100b described in the present embodiment and the substrate structure 100a provided in the previous embodiments may be formed by substantially performing the same manufacturing process, and the difference therebetween lies in that the third laser beam L3′ is not perpendicular to the upper surface 112 of the insulation base material 110. Instead, there is an included angle between the direction of the third laser beam L3′ and the upper surface 112 of the insulation base material 110. Accordingly, the inner wall of the resultant third opening T3′ is an inclined surface. Here, the intersection between the inner wall of the third opening T3′ and the inner wall of the second opening T2′ defines the neck end portion E2′, and the neck end portion E2′ is actually an end point and located at the center of the through hole H′.

To sum up, the location of the neck end portion of the through hole is at the center of the through hole. Hence, when a via filling plating process is subsequently performed on the substrate structure, the conventional void issue (i.e., the end of the through hole with the small diameter is first filled with and sealed by the deposited conductive material) may be prevented. Consequently, the design of the substrate structure described herein is conducive to improvement of yield of subsequent manufacturing processes. In addition, the location of the neck end portion is adjusted through the third laser treatment, thus increasing reliability of the substrate structure in subsequent manufacturing processes.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

1. A substrate structure comprising:
an insulation base material; and
a through hole passing through the insulation base material and having a first opening, a second opening, and a third opening communicated with one another, the third opening being located between the first opening and the second opening, wherein a first included angle is formed between an inner wall of the first opening and an inner wall of the third opening, a second included angle is formed between an inner wall of the second opening and the inner wall of the third opening, a minimum diameter of the third opening is at a center of the through hole and defines a neck end portion, and diameters of the first opening and the second opening gradually decrease in a direction toward the neck end portion.

2. The substrate structure as recited in claim 1, wherein a thickness of the insulation base material ranges from about 100 μm to about 400 μm.

3. The substrate structure as recited in claim 1, wherein the inner wall of the third opening is a vertical surface, and the diameter of the third opening has a constant value.

4. The substrate structure as recited in claim 3, wherein the second included angle is substantially greater than the first included angle.

5. The substrate structure as recited in claim 1, wherein the inner wall of the third opening is an inclined surface, and the diameter of the third opening gradually decreases in a direction from the first opening to the neck end portion.

6. The substrate structure as recited in claim 5, wherein the second included angle is substantially greater than the first included angle.

7. A manufacturing method of a substrate structure, comprising:
providing an insulation base material, the insulation base material having an upper surface and a lower surface opposite to each other;
performing first laser treatment on the upper surface of the insulation base material to form a first opening;
performing second laser treatment on the lower surface of the insulation base material to form a second opening, wherein the second opening communicates with the first opening, and the communicated first and second openings define an initial neck end portion; and
performing third laser treatment on the upper surface or the lower surface of the insulation base material according to a location of the initial neck end portion to form a third opening, wherein the first opening, the second opening, and the third opening are communicated with one another and define a through hole, the third opening is located between the first opening and the second opening, a first included angle is formed between an inner wall of the first opening and an inner wall of the third opening, a second included angle is formed between an inner wall of the second opening and the inner wall of the third opening, a minimum diameter of the third opening is at a center of the through hole and defines a neck end portion, and diameters of the first opening and the second opening gradually decrease in a direction toward the neck end portion.

8. The manufacturing method of the substrate structure as recited in claim 7, wherein a thickness of the insulation base material ranges from about 100 μm to about 400 μm.

9. The manufacturing method of the substrate structure as recited in claim 7, wherein laser energy of the first laser treatment, laser energy of the second laser treatment, and laser energy of the third laser treatment all range from about 5 mJ to about 15 mJ, and laser pulse time of the first laser treatment, laser pulse time of the second laser treatment, and laser pulse time of the third laser treatment all range from about 5 microseconds to about 20 microseconds.

10. The manufacturing method of the substrate structure as recited in claim 7, wherein the inner wall of the third opening is a vertical surface, and the diameter of the third opening has a constant value.

11. The manufacturing method of the substrate structure as recited in claim 10, wherein the second included angle is substantially greater than the first included angle.

12. The manufacturing method of the substrate structure as recited in claim 7, wherein the inner wall of the third opening is an inclined surface, and the diameter of the third opening gradually decreases in a direction from the first opening to the neck end portion.

13. The manufacturing method of the substrate structure as recited in claim 12, wherein the second included angle is substantially greater than the first included angle.
